(19) United States
(12) Patent Application Publication
(10) Pub. No.: US 2016/0242323 A1
(43) Pub. Date: Aug. 18, 2016

(54) RACK TYPE DATA CENTER

(71) Applicant: DELTA ELECTRONICS, INC., Taoyuan County (TW)

(72) Inventors: Peng-Yuan CHEN, Taoyuan County (TW); Chung-Ju TSAI, Taoyuan County (TW); Chia-Hao LIANG, Taoyuan County (TW)

(21) Appl. No.: 14/694,309

(22) Filed: Apr. 23, 2015

(30) Foreign Application Priority Data
Feb. 13, 2015 (TW) 104104957

(51) Int. Cl. H05K 7/20

(52) U.S. Cl. CPC H05K 7/20745

(57) ABSTRACT

A rack type data center includes a rack, a column of servers and an air conditioner module. A server room and an air conditioner room are formed in the rack. A primary inlet valve is disposed on the server room, and an outlet valve is disposed on the server room. An inlet fan is arranged between the server room and the air conditioner room; the servers are arranged in the server room; a cold aisle and a hot aisle are formed in the server room, and the inlet fan is arranged corresponsive to the cold aisle. The air conditioner module includes a coil installed in the air conditioner room, and the primary inlet valve is disposed between the coil and the inlet fan. The outlet valve is used to exhaust air in the hot aisle. The fan introduces airflow into the cold aisle without passing through the coil.

### FIELD OF THE INVENTION

The present invention relates to a rack type data center, and more particularly to a power-saving rack type data center that provides a cooling effect by the circulation of external air.

### BACKGROUND OF THE INVENTION

In a general organization such as a small/medium company or a primary/secondary school, the work requirement of a data center of such organization is relatively smaller, and it is not economical to build a dedicated server room to install servers, so that most servers are put in a room freely and cooled by indoor air conditioners. Without a design of cold and hot aisles, the airflow circulation path may be too long, and a short hot air circulation may result easily. As a result, the indoor temperature is very high. Obviously, the cooling efficiency of the aforementioned configuration is much lower than that of the dedicated server room.

To meet a low usage requirement, a rack type data center is designed, wherein a cold aisle and a hot aisle are partitioned by the servers in the rack, and a compact direct-expansion air conditioner is installed in the rack, so that an independent circulation system is built in the rack and provided for reducing the power consumption of the air-conditioning. In addition, the rack type data center has the advantage of being installed and moved easily.

However, the conventional rack type data center generally comes with a poor airflow management. If the coil of the air conditioner is not working, the circulated airflow still will pass through the coil, thus not just wasting unnecessary power for the airflow movement only, but also increasing the workload of the fan or lowering the cooling efficiency due to dust may be accumulated onto the coil easily, as well as shortening the cleaning and maintenance cycle of the coil.

In view of the aforementioned shortcomings, the inventor of the present invention based on years of experience in the related industry to conduct extensive researches and experiments to develop and design the present invention to overcome the aforementioned shortcomings of the prior art.

### SUMMARY OF THE INVENTION

Therefore, it is a primary objective of the present invention to provide a power-saving rack type data center that provides a cooling effect by circulating external air.

To achieve the aforementioned objective, the present invention provides a rack type data center comprising a rack, a column of servers, and an air conditioner module. A server room and an air conditioner room are formed in the rack, and the air conditioner room includes a primary inlet valve and an outlet valve, and an inlet fan is installed between the server room and the air conditioner room. The server is installed in the server room, and a cold aisle and a hot aisle separated from each other are formed in the server room by being enclosed by the server, and the inlet fan is configured to be corresponsive to the cold aisle. The air conditioner module includes a coil installed in the air conditioner room, and the primary inlet valve is disposed between the coil and the inlet fan. The outlet valve is provided for passing air into the hot aisle and discharging the air out of the rack.

In the rack type data center of the present invention, when the inlet fan guides airflow to the cold aisle, the primary inlet valve is provided for guiding the natural airflow without passing through the coil to achieve the power-saving effect.

### BRIEF DESCRIPTION OF THE DRAWINGS

FIG. 1 is a schematic view of a rack type data center in accordance with a preferred embodiment of the present invention;

FIG. 2 is a schematic view of a rack type data center operated in a power-saving circulation mode in accordance with a preferred embodiment of the present invention;

FIG. 3 is a schematic view of a rack type data center operated in a closed circulation mode in accordance with a preferred embodiment of the present invention;

FIG. 4 is a schematic view of a rack type data center operated in a natural air intake mode in accordance with a preferred embodiment of the present invention; and

FIG. 5 is a schematic view of a rack type data center operated in an external air circulation mode in accordance with a preferred embodiment of the present invention.

### DESCRIPTION OF THE PREFERRED EMBODIMENTS

The technical contents of the present invention will become apparent with the detailed description of preferred embodiments accompanied with the illustration of related drawings as follows. It is noteworthy that the drawings are provided for the purpose of illustrating the present invention, but not intended for limiting the scope of the invention.

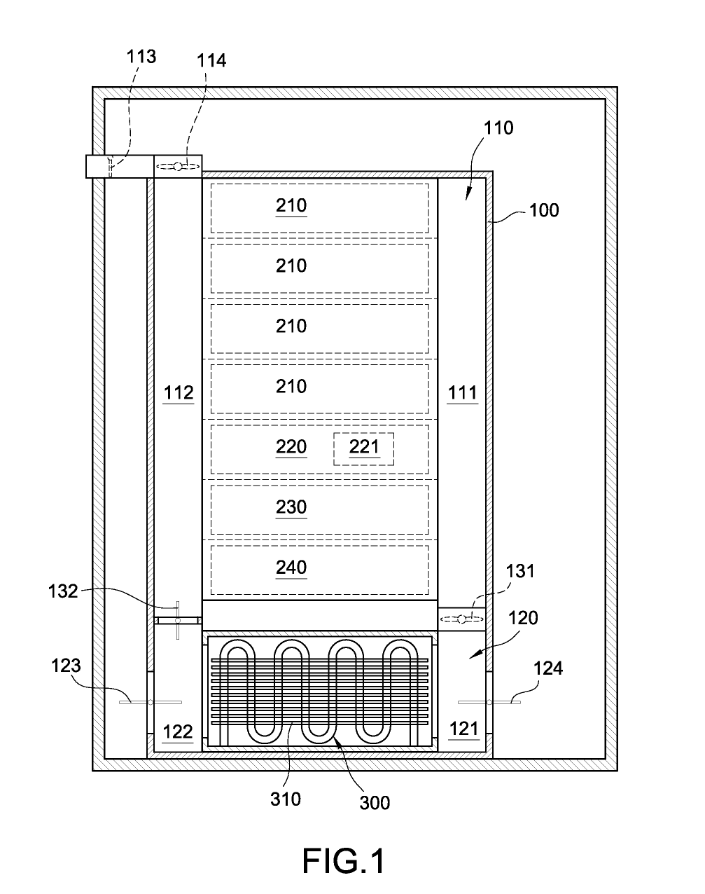

With reference to FIG. 1 for a rack type data center in accordance with a preferred embodiment of the present invention, the rack type data center comprises a rack 100, a column of servers 210, a power supply module 220, a power distribution module 230, an environmental management system (EMS) module 240, and an air conditioner module 300.

In this embodiment, the rack 100 is preferably in the shape of a rectangular pillar and erected vertically. The interior of the rack 100 is partitioned into a server room 110 and an air conditioner room 120. In this embodiment, the server room 110 is preferably arranged under the air conditioner room 120. The server room 110 includes an outlet valve 113 which is selectively opened and shut and provided for discharging the air in the server room 110 out of the rack 100. The outlet valve 113 may have an outlet fan 114 to assist discharging the air, and the outlet valve 113 may be opened or shut. A circulation valve 132 disposed between the server room 110 and the air conditioner room 120 is selectively opened and shut and provided for returning the air in the server room 110 to the air conditioner room 120. The air conditioner room 120 includes a secondary inlet valve 123 which is selectively opened and shut, and a primary inlet valve 124 which is selectively opened and shut. It is noteworthy that both secondary inlet valve 123 and primary inlet valve 124 may be opened or shut. An inlet fan 131 is installed between the server room 110 and the air conditioner room 120 for driving the air to flow in the rack 100.

Preferably, each server 210 includes a cooling fan (not shown in the figure) installed therein and provided for sucking air from the front of the servers 210 to cool the servers 210, and discharging the hot air after it passes through the rear of the servers 210. The servers 210 are preferably arranged vertically into a column, and both respective front and rear sides of the column of servers 210 are aligned precisely with one another. The column of servers 210 is disposed in the server room 110 and provided for forming a cold aisle 111 and a hot aisle 112 which are separated from each other and formed in the server room 110 by being enclosed by the column of servers 210, and the front of the server 210 is disposed in the cold aisle 111, and the rear of the server 210 is disposed in the hot aisle 112, and the inlet fan 131 is configured to be corresponsive to the cold aisle 111 for guiding air into the cold aisle 111. The outlet valve 113 is interconnected to the hot aisle 112 and capable of discharging the hot air in the hot aisle 112 out of the rack 100. The circulation valve 132 is disposed between the hot aisle 112 and the air conditioner room 120 for passing the air in the hot aisle 112 through the air conditioner room 120 and returning the cold air to the cold aisle 111.

In this embodiment, the air conditioner module 300 includes a coil 310 installed in the air conditioner room 120, and the secondary inlet valve 123 and the primary inlet valve 124 are separated from each other and disposed on both sides of the coil 310 respectively, and the primary inlet valve 124 is disposed between the coil 310 and the inlet fan 131.

A front air passage 121 and a rear air passage 122 separated from each other are formed in the conditioner room 120 by being enclosed by the coil 310. Wherein, the rear air passage 122 is interconnected to the hot aisle 112, and the circulation valve 132 is disposed between the rear air passage 122 and the hot aisle 112. The front air passage 121 is interconnected to the cold aisle 111, and the inlet fan 131 is installed between the front air passage 121 and the cold aisle 111, and the primary inlet valve 124 is disposed in the front air passage 121, so that the inlet fan 131 can drive the air to flow in the rack 100. The rear air passage 122 is interconnected to the hot aisle 112, and the circulation valve 132 is disposed between the hot aisle 112 and the rear air passage 122, and the secondary inlet valve 123 is disposed in the rear air passage 122.

The coil 310 of the air conditioner module 300 may be connected to an ice water machine (not shown in the figure) for supplying ice water into the coil 310, but the present invention is not limited to such arrangement only. For example, the air conditioner module 300 may be a direct-expansion cooling pipeline, and a coolant may be filled into the coil 310, and the coil 310 is connected to a compressor (not shown in the figure) to drive and circulate the coolant in the coil 310, and the compressor may be installed in the air conditioner room 120 or outside the rack 100.

The power supply module 220 is installed in the server room 110 for supplying electric power to the server 210. The power supply module 220 includes a set of backup power supply unit 221, so that if the external power is interrupted, the backup power supply unit 221 will be able to supply power to the server 210 within a specific time for emergency handling (such as saving data files and shutting down the severs to prevent data loss and equipment damage). The EMS module 240 is installed in the server room 110 for monitoring the operating condition of the server 210. The power distribution module 230 is installed in the server room 110 for distributing the power supplied by the power supply module 220 to each server 210 according to operation requirements, and the power distribution module 230 may be used for selectively distributing power to the air conditioner module 300 and the backup power supply unit 221.

In this embodiment, the power supply module 220, the power distribution module 230 and the EMS module 240 are arranged in a row, and the air in the cold aisle 111 can pass through the power supply module 220, the power distribution module 230 and the EMS module 240 and enter into the hot aisle 112, so as to cool the power supply module 220, the power distribution module 230 and the EMS module 240.

The rack type data center of the present invention is operated in an appropriate working mode based on the ambient temperature of the cold aisle 111 and the hot aisle 112. A predetermined temperature range is set as a basis for selecting the working mode. For example, the predetermined temperature range is maintained within the range of 27˜32, but the present invention is not limited to such temperature range only. Preferably, the temperature inside the cold aisle 111 is maintained within the predetermined temperature range.

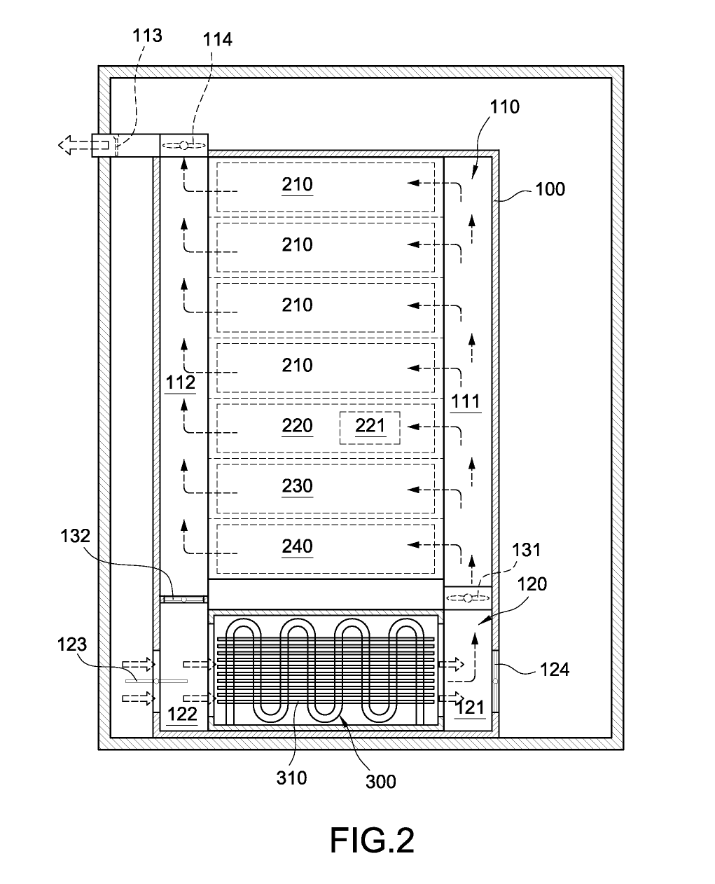

In FIG. 2, when the ambient temperature falls within the predetermined temperature range and the temperature of the cold aisle 111 is greater than the predetermined temperature range, the rack type data center of the present invention is preferably operated in the power-saving circulation mode, wherein the external air is guided into the air conditioner room 120, cooled by the air conditioner module 300, and then introduced into the server room 110 for cooling the server 210, the power supply module 220, the power distribution module 230 and the EMS module 240 inside the server room 110.

In the power-saving circulation mode, the primary inlet valve 124 and the circulation valve 132 are shut, the secondary inlet valve 123 and the outlet valve 113 are opened, and the inlet fan 131, the outlet fan 114 and the coil 310 are turned on for the operation. During the operation of the inlet fan 131, a negative pressure is formed in the front air passage 121 of the air conditioner room 120, so that the external air can be guided into the rear air passage 122 of the air conditioner room 120 through the secondary inlet valve 123, and the external air flowing from the rear air passage 122 and passing through the coil 310 is cooled before entering into the front air passage 121. The inlet fan 131 guides the cold air in the front air passage 121 into the cold aisle 111, wherein the cold air passes through the server 210, the power supply module 220, the power distribution module 230 and the EMS module 240 and absorbs heat to form a hot air, and then the hot air is discharged into the hot aisle 112. The outlet fan 114 discharges the hot air in the hot aisle 112 out of the rack 100 through the outlet valve 113.

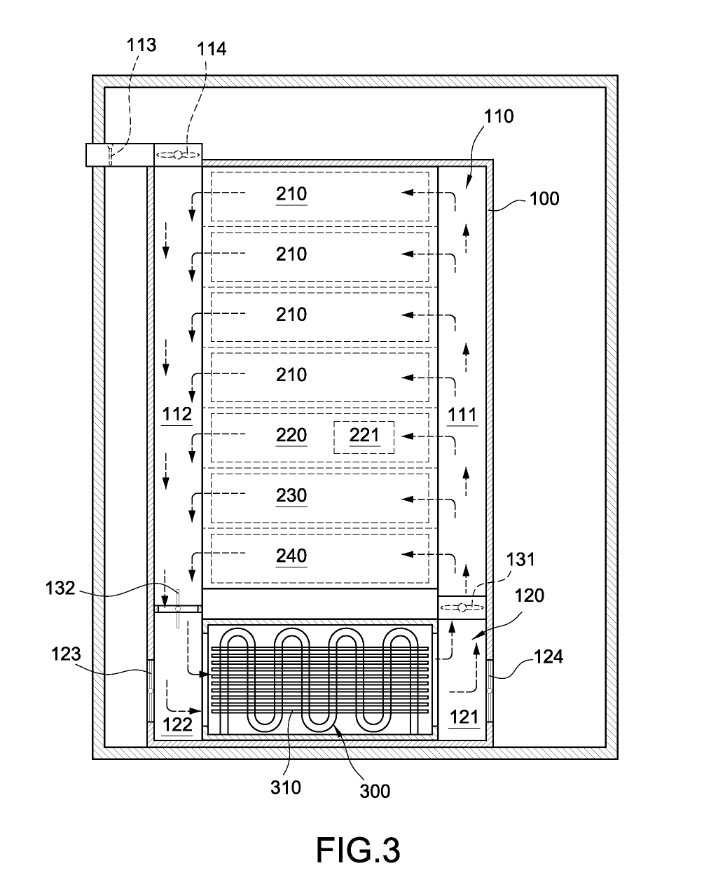

In FIG. 3, if the ambient temperature is greater than the predetermined temperature range and the temperature of the cold aisle is greater than the predetermined temperature range, the rack type data center of the present invention will not introduce external air into the rack, but it will be operated in a closed circulation mode.

In the closed circulation mode, the secondary inlet valve 123, the primary inlet valve 124 and the outlet valve 113 are shut, the circulation valve 132 is opened, the inlet fan 131 and the coil 310 are turned on and operated, and the outlet fan 114 is turned off. In the operation of the inlet fan 131, the air is circulated in the rack 100, and the air flowing through the coil 310 is cooled to form a cold air, and the cold air is passed through the front air passage 121 and guided into the cold aisle 111, wherein the cold air passes through the server 210, the power supply module 220, the power distribution module 230 and the EMS module 240 and absorbs heat to form a hot air, and the hot air is discharged into the hot aisle 112. The hot air passes through the circulation valve 132 and returns to the rear air passage 122, and the hot air passing through the coil 310 is cooled to form a cold air, and the cold air is recycled.

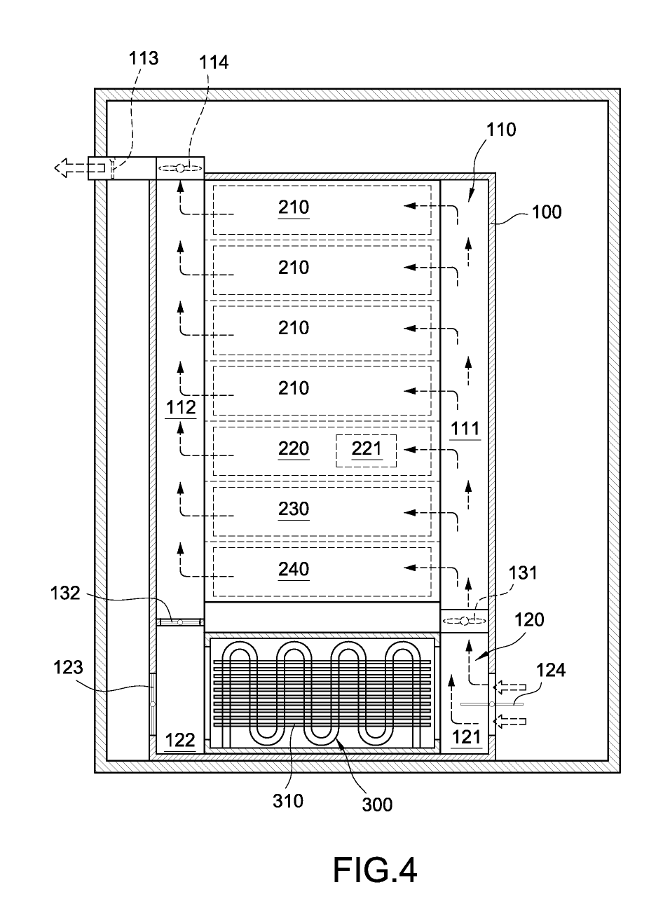

In FIG. 4, when the temperature of the cold aisle falls within the predetermined temperature range, or the air conditioner module 300 breaks down, the rack type data center of the present invention is preferably operated in a natural air intake mode, wherein external air is guided into the air conditioner room 120 and introduced into the server room 110 through the primary inlet valve 124 for cooling the server 210, the power supply module 220, the power distribution module 230 and the EMS module 240. After the aforementioned process, the cool external air absorbs heat to form a hot air, and the hot air is discharged out of the rack 100 through the outlet valve 113.

In the natural air intake mode, the primary inlet valve 124 is opened, the secondary inlet valve 123, the circulation valve 132 and the outlet valve 113 are shut, the inlet fan 131 and the outlet fan 114 are turned on and operated, and the coil 310 is turned off. When the inlet fan 131 is operated, a negative pressure is formed in the front air passage 121 of the air conditioner room 120, so that the external air can enter into the front air passage 121. The inlet fan 131 guides the cold air in the front air passage 121 into the cold aisle 111, wherein the cold air passes through the server 210, the power supply module 220, the power distribution module 230 and the EMS module 240 and absorbs heat to form a hot air, and the hot air is discharged into the hot aisle 112. The hot air in the hot aisle 112 is discharged out of the rack 100 through the outlet fan 114.

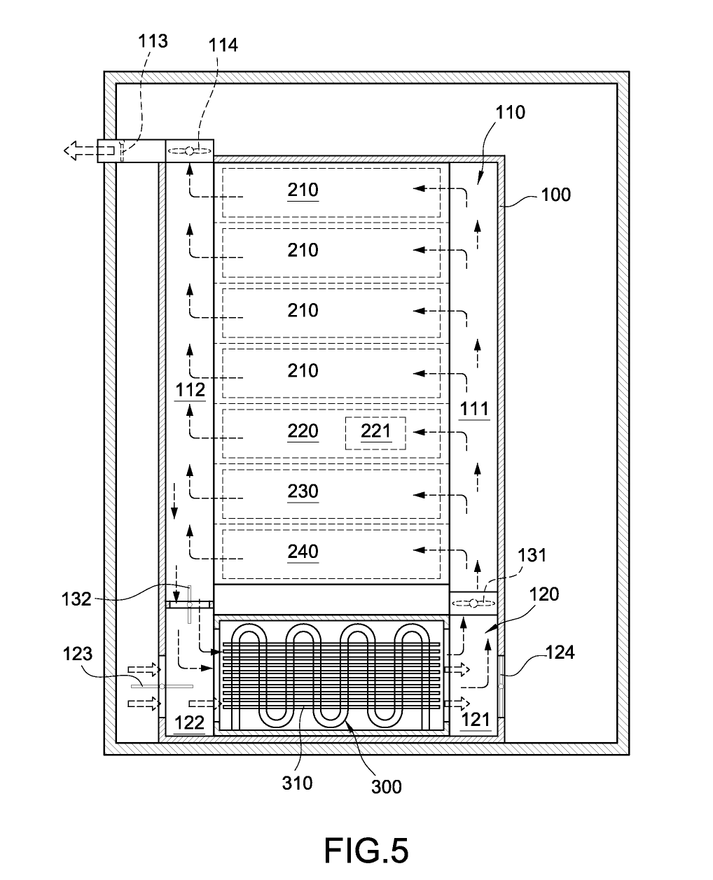

In FIG. 5, when the ambient temperature is much smaller than the predetermined temperature range, the rack type data center of the present invention is preferably operated in an external air circulation mode, wherein external air is guided into the server room 110 for cooling the server 210, the power supply module 220, the power distribution module 230 and the EMS module 240.

In the external air circulation mode, the secondary inlet valve 123, the circulation valve 132 and the outlet valve 113 are opened, the primary inlet valve 124 is shut, the inlet fan 131 and the outlet fan 114 are turned on and operated, and the coil 310 is turned off. In the operation of the inlet fan 131, a negative pressure is formed in the front air passage 121 of the air conditioner room 120, so that the external air can be guided into the front air passage 121 of the air conditioner room 120 through the secondary inlet valve 123 and the coil 310, and the inlet fan 131 further guides the external air in the front air passage 121 into the cold aisle 111, wherein the external air passes through the server 210, the power supply module 220, the power distribution module 230 and the EMS module 240 and absorbs heat to form a hot air, and the hot air is then discharged into the hot aisle 112. A portion of hot air is discharged out of the rack 100 by the outlet fan 114, and the remaining hot air passes through the circulation valve 132 and returns to the rear air passage 122, and the hot air and the external air guided into the primary inlet valve 124 are mixed to increase the temperature of the external air to the predetermined temperature range for recycle. Wherein, the circulation valve 132 may be partially opened to adjust the quantity of return flow.

Preferably, if only the primary inlet valve 124, the circulation valve 132 and the outlet valve 113 are installed without any secondary inlet valve 123, the rack type data center of the present invention may shut the primary inlet valve 124 and the outlet valve 113 and open the circulation valve 132 to carry out the closed circulation mode, or may open the primary inlet valve 124 and the outlet valve 113 and shut the circulation valve 132 to carry out the natural air intake mode.

Preferably, if only the primary inlet valve 124, the secondary inlet valve 123 and the outlet valve 113 are installed without any circulation valve 132, the rack type data center of the present invention may shut the secondary inlet valve 123 and the outlet valve 113 and open the primary inlet valve 124 to carry out the power-saving circulation mode, or may open the primary inlet valve 124 and the outlet valve 113 and shut the secondary inlet valve 123 to carry out the natural air intake mode.

The rack type data center of the present invention guides air into the cold aisle 111 through the primary inlet valve 124, or guides air into the cold aisle 11 through the secondary inlet valve 123 and the coil 310. In the operation of the rack type data center in the external air circulation mode, the external air will not pass through the coil 310 to prevent a flow retardation, so as to achieve the effects of reducing the workload of the inlet fan 131 and the outlet fan 114 and saving power.

While the invention has been described by means of specific embodiments, numerous modifications and variations could be made thereto by those skilled in the art without departing from the scope and spirit of the invention set forth in the claims.

What is claimed is:

1. A rack type data center, comprising:
a rack, having a server room and an air conditioner room formed therein, a primary inlet valve selectively opened and shut and disposed in the air conditioner room, an inlet fan installed between the server room and the air conditioner room, and an outlet valve disposed in the sever room;
a column of servers, installed in the server room, and enclosed in the server room to form a cold aisle and a hot aisle that are separated from each other, and the inlet fan being configured to be corresponsive to the cold aisle; and
an air conditioner module, including a coil installed in the air conditioner room, and the primary inlet valve being disposed between the coil and the inlet fan;
thereby, the rack type data center is capable of introducing airflow from the air conditioner room into the cold aisle by the inlet fan, and the outlet valve is provided for passing the air into the hot aisle and discharging the air out of the rack.

2. The rack type data center of claim 1, wherein when the primary inlet valve is turned on, the rack type data center is capable of introducing airflow through the primary inlet valve into the cold aisle by the inlet fan directly without passing through the coil.

3. The rack type data center of claim 1, wherein the outlet valve further includes an outlet fan.

4. The rack type data center of claim 1, further comprising a circulation valve selectively opened and shut and disposed between the hot aisle and the air conditioner room, for passing the air in the hot aisle through the air conditioner room and returning the air to the cold aisle.

5. The rack type data center of claim 4, wherein the coil has a front air passage and a rear air passage separated from each other and formed in the air conditioner room by being enclosed by the coil, and the rear air passage is interconnected to the hot aisle, and the circulation valve is disposed between the rear air passage and the hot aisle, and the front air passage is interconnected to the cold aisle, and the inlet fan is installed between the front air passage and the cold aisle, and the inlet fan is provided for driving the air in the hot aisle into the rear air passage through the circulation valve, and then returning the air from the front air passage to the cold aisle after passing through the coil.

6. The rack type data center of claim 1, wherein the coil has a front air passage and a rear air passage separated from each other and formed in the air conditioner room by being enclosed by the coil, and the rear air passage is interconnected to the hot aisle, and the rear air passage has a secondary inlet valve selectively opened and shut, and the front air passage is interconnected to the cold aisle, and the inlet fan is installed between the front air passage and the cold aisle, and the primary inlet valve is installed in the front air passage.

7. The rack type data center of claim 6, wherein when the secondary inlet valve is opened, the rack type data center is capable of guiding air to flow through the secondary inlet valve by the inlet fan, and then guiding the air to flow into the cold aisle from the front air passage after the air passes through the coil.

8. The rack type data center of claim 1, wherein the coil is interconnected to a compressor and driven by the compressor, and the compressor is installed in the air conditioner room.

9. The rack type data center of claim 1, wherein the coil is interconnected to a compressor and driven by the compressor, and the compressor is installed outside the rack.

10. The rack type data center of claim 1, further comprising a power supply module installed in the server room for supplying power required by the column of servers.

11. The rack type data center of claim 10, wherein the power supply module includes a backup power supply unit.

12. The rack type data center of claim 10, wherein the power supply module and the column of servers are arranged in a row, and the air in the cold aisle can pass through the power supply module and enter into the hot aisle.

13. The rack type data center of claim 10, further comprising a power distribution module installed in the server room for distributing the power supplied to the power supply module.

14. The rack type data center of claim 13, wherein the power supply module and the power distribution module are arranged adjacent to the column of servers, so that the air in the cold aisle can pass through the power supply module and the power distribution module and enter into the hot aisle.

15. The rack type data center of claim 1, further comprising a monitoring module installed in the sever room for monitoring the operating condition of the column of servers.

16. The rack type data center of claim 15, wherein the monitoring module and the column of servers are arranged in a row, so that the air in the cold aisle can pass through the monitoring module and enter into the hot aisle.
